(19) United States
(12) Patent Application Publication
(10) Pub. No.: US 2026/0064013 A1
(43) Pub. Date: Mar. 5, 2026

(54) PROCESS CONTROL FOR DOSE, FOCUS, AND OVERLAY USING WEIGHTING MAPS BASED ON SPATIAL PROCESS KPIS

(71) Applicant: KLA Corporation, Milpitas, CA (US)

(72) Inventor: Philip Groeger, Dresden (DE)

(21) Appl. No.: 18/816,836

(22) Filed: Aug. 27, 2024

(51) Int. Cl. G03F 7/00

(52) U.S. Cl. CPC G03F 7/70633; G03F 7/705; G03F 7/70558; G03F 7/70641

(57) ABSTRACT

A modeled correction may be generated based on metrology measurements and a weighting map. Residuals between the modeled correction and the metrology measurements may be weighted according to the weighting map. The modeled correction may be weighed via the weighting map according to a position at which the metrology measurements were generated on a sample. The modeled correction may include dose, focus, and overlay. A process tool may be controlled based on the modeled correction to control the dose, focus, and overlay.

### TECHNICAL FIELD

The present disclosure generally relates to semiconductor metrology, and, more particularly, to process control using metrology.

### BACKGROUND

Current trends in the manufacturing of semiconductor devices by processing of the semiconductor wafers mean that overlay and critical dimension budgets shrink with shrinking ground rules and the semiconductor manufacturing processes are becoming more aggressive. Examples of such aggressive semiconductor manufacturing processes include, but are not limited to, multiple patterning, and high aspect ratio etching or deposition of exotic materials on a surface of the semiconductor wafer. The non-uniformity of some of the semiconductor manufacturing processes over the semiconductor wafer surface and a plurality of semiconductor manufacturing process steps may result in non-uniform stress being applied to the semiconductor wafer.

Overlay error and critical dimension error may occur when processing the semiconductor wafer. The overlay error may occur when the semiconductor wafer deforms from one process step to a subsequent process step, e.g. from one lower layer to a subsequent layer on top of the lower layer, patterns in the upper layer become misaligned with respect to patterns in the lower layer. The critical dimension error may occur due to non-uniformities introduced by etch processes, spin coating, baking, and the like. For the error free functioning of the semiconductor device, the relative position of the patterns on the different layers to each other is relevant. The reason for this misalignment can be multi-fold and may depend on the different process steps.

Difficulties may arise in evaluating and controlling the semiconductor manufacturing process to identify and/or correct for such issues in the semiconductor manufacturing process. Therefore, it would be advantageous to provide a device, system, and method that cures the shortcomings described above.

### SUMMARY

A controller of a metrology system is described, in accordance with one or more embodiments of the present disclosure. The controller may include: one or more processors configured to execute program instructions causing the one or more processors to: receive one or more metrology measurements of a sample; generate a weighting map associated with the sample, wherein the weighting map spatially varies across the sample; and generate a modeled correction based on the one or more metrology measurements and the weighting map, wherein the modeled correction is weighed via the weighting map according to a position at which the one or more metrology measurements were generated on the sample.

A metrology system is described, in accordance with one or more embodiments of the present disclosure. The metrology system may include: a controller including: one or more processors configured to execute program instructions causing the one or more processors to: receive one or more metrology measurements of a sample; generate a weighting map associated with the sample, wherein the weighting map spatially varies across the sample; and generate a modeled correction based on the one or more metrology measurements and the weighting map, wherein the modeled correction is weighed via the weighting map according to a position at which the one or more metrology measurements were generated on the sample.

A method is described, in accordance with one or more embodiments of the present disclosure. The method may include: receiving one or more metrology measurements of a sample; generating a weighting map associated with the sample, wherein the weighting map spatially varies across the sample; and generating a modeled correction based on the one or more metrology measurements and the weighting map, wherein the modeled correction is weighed via the weighting map according to a position at which the one or more metrology measurements were generated on the sample.

### BRIEF DESCRIPTION OF THE DRAWINGS

The numerous advantages of the disclosure may be better understood by those skilled in the art by reference to the accompanying figures in which:

FIG. 1A depicts a simplified block diagram of a metrology system, in accordance with one or more embodiments of the present disclosure.

FIG. 1B depicts a simplified block diagram of a metrology sub-system of the metrology system, in accordance with one or more embodiments of the present disclosure.

FIG. 2 depicts a flow diagram of a method, in accordance with one or more embodiments of the present disclosure.

FIG. 3A depicts an out-of-specification map after correcting a sample according to a modeled correction determined from metrology measurements which are not weighted with a weighting map.

FIG. 3B depicts an out-of-specification map after correcting a sample according to a modeled correction determined from metrology measurements which are weighted with a weighting map, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to process control for dose, focus, and overlay using weighting maps. A modeled correction may be generated based on the metrology measurements and the weighting map. Residuals between the modeled correction and the metrology measurements may be weighted according to the weighting map. The modeled correction may be weighed via the weighting map according to a position at which the metrology measurements were generated on a sample. The modeled correction may include dose, focus, and overlay. A process tool may be controlled based on the modeled correction to control the dose, focus, and overlay.

U.S. Patent Publication Number US20240093985A1, titled “System and method for acquiring alignment measurements of structures of a bonded sample”; U.S. Pat. No. 10,234,401B2, titled “Method of manufacturing semiconductor devices by using sampling plans”; U.S. Pat. No. 10,310,490B2, titled “Method and apparatus of evaluating a semiconductor manufacturing process”; U.S. Pat. No. 10,545,412B2, titled “Statistical overlay error prediction for feed forward and feedback correction of overlay errors, root cause analysis and process control”; U.S. Pat. No. 10,867,877B2, titled “Targeted recall of semiconductor devices based on manufacturing data”; U.S. Pat. No. 11,092,901B2, titled “Wafer exposure method using wafer models and wafer fabrication assembly”; U.S. Pat. No. 11,181,830B2, titled “Lithographic apparatus and method of controlling a lithographic apparatus”; U.S. Pat. No. 11,221,300B2, titled “Determining metrology-like information for a specimen using an inspection tool”; U.S. Pat. No. 11,293,970B2, titled “Advanced in-line part average testing”; U.S. Pat. No. 11,429,091B2, titled “Method of manufacturing a semiconductor device and process control system for a semiconductor manufacturing assembly”; U.S. Pat. No. 9,052,709B2, titled “Method and system for providing process tool correctables”; U.S. Pat. No. 11,340,060B2, titled “Automatic recipe optimization for overlay metrology system”; are each incorporated herein by reference in the entirety.

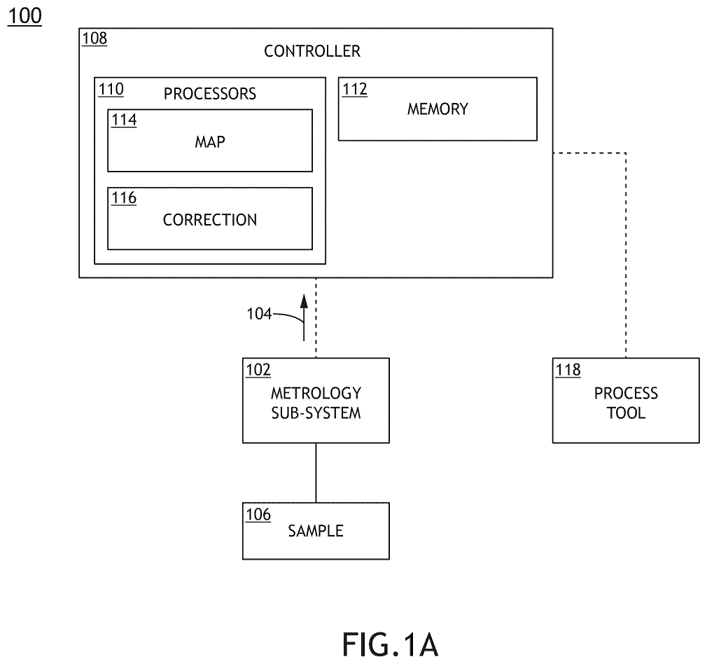

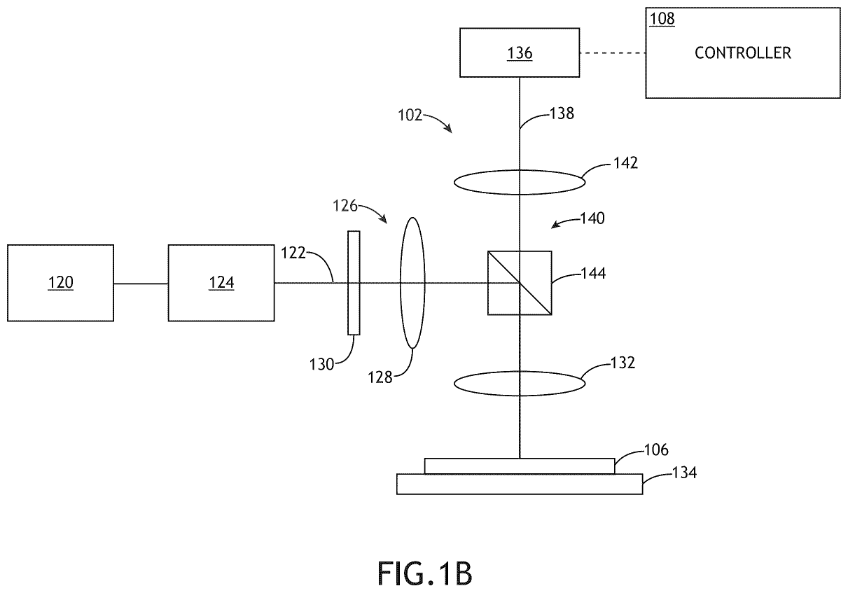

FIG. 1A depicts a metrology system 100, in accordance with one or more embodiments of the present disclosure. The metrology system 100 may include a metrology sub-system 102. The metrology system 100 may generally include any number or type of metrology sub-systems 102 and each metrology sub-system 102 may generally include any number or type of sub-systems (e.g., metrology and/or inspection sub-systems). The metrology sub-system 102 may include one or more metrology tools.

The metrology sub-system 102 may include any combination of metrology sub-systems such as, but not limited to, optical metrology systems (e.g., light-based metrology systems), scatterometry metrology sub-systems, particle-based metrology systems, probe-based systems, an electron beam metrology sub-system (e.g., scanning electron microscope metrology sub-system or the like), or the like.

The metrology sub-system 102 may characterize and/or screen a sample 106. The metrology sub-system 102 may characterize and/or screen the sample 106 at various steps of the manufacturing process in which the sample 106 is manufactured. The metrology sub-system 102 may include any type of metrology tool suitable for any type of metrology and/or inspection measurements at any point of the manufacturing process.

The sample 106 may include any number and type of samples. For example, the sample 106 may be a wafer (e.g., a semiconductor wafer), a pre-bonded substrate (e.g., pre-bonded die), a coupled sample formed from two substrates (e.g., die to wafer, wafer to wafer, die to die, and the like), a pre-diced wafer, or any other type or combination of samples. For instance, the sample 106 may include a coupled sample formed from two substrates coupled together at an interface. Note that, while a sample 106 may be described in terms of being or including a “die”, such a term is nonlimiting and any descriptions and methodologies herein may be applicable to a “chiplet”, a “chip”, multiple dies/chiplets collectively coupled in-plane together, a full wafer, a partially diced wafer, a plurality of multiple stacked bonded dies/chiplets/wafers configured to be bonded to another wafer, and the like.

The sample 106 may be formed from any material or combination of materials including, but not limited to, a wafer substrate, a semiconductor, a metal, a polymer, a glass, a crystalline material, semiconductor-on-insulator (SOI), or the like. A wafer substrate may be a thin disc that includes a substrate material. The substrate material may include a semiconducting material. For example, the wafer substrate may be a semiconductor wafer, a glass substrate including one or more semiconducting layers, or an SOI (silicon-on-insulator) wafer, by way of example.

The sample 106 may include structures. The structures may be formed on or in a wafer substrate of the sample 106. The structures may also be referred to as features, deposited films, fabricated features, and the like. The structures may be any structure to which a measurement may be taken. For example, a structure generally could be, but is not limited to, an electrically functional structure such as a portion of a logic gate or transistor, a nonfunctional structure such as a dedicated overlay target, an edge of a die/wafer, or any other measurable structure. The structures may include trenches extending from a main surface at a front side of the wafer substrate into the wafer substrate. The trenches may be filled with a material different from a surrounding substrate material. The structures may project from a main surface at a front side of the wafer substrate. The structures which project from the main surface may include, e.g., pillars, stripe-shaped ribs, line patterns, photoresist structures, and the like. The structures may be semiconductor layers, semiconductor elements, semiconductor devices, or the like. The structures may form memory devices, microprocessors, logic circuits, analog circuits, power semiconductor devices, and the like. The structures may be formed on a main surface of a wafer substrate. The structures may include an activated or deactivated photoactive component. The structures may be obtained by developing an exposed photoresist layer. The structures may include a plurality of laterally separated resist features.

The structures of the sample 106 may be manufactured during a semiconductor manufacturing process. There may be many process steps in the semiconductor manufacturing process that may cause variations of overlay (OVL) between layers or variations of critical dimensions (CD) of the structures. The variations may change over a chip/die per field, over a field, over the sample 106, and/or over a lot including multiple of the samples 106.

The metrology system 100 may generate metrology measurements 104 of the sample 106. For example, the metrology sub-system 102 may generate the metrology measurements 104. The metrology measurements 104 may be metrology measurements of the structures of the sample 106.

The metrology measurements 104 may be generated after processing of the structures. For example, the metrology measurements 104 may be generated after patterning of a lithographic layer, deposition, etching, exposure, development, and the like. The structures may be formed via processes such as heating, layer formation, patterning, etching, grinding, or implanting.

The metrology measurements 104 may be from different locations of the sample 106. The metrology system 100 may generate the metrology measurements 104 at metrology sites. The metrology sites may be distributed across the sample 106. The metrology sites may have circular, elliptical or rectangular shape. The size of the metrology sites depends on the measurement method. For example, a diameter or edge length of the metrology sites may be about 100 μm for scatterometric methods and about 1 μm for measurements using electron microscopy. The metrology sites at which the metrology measurements are generated may be independent of the results of an inspection process performed on the sample 106. Since locations on the specimen at which metrology is performed may be selected independently of inspection results, the metrology measurements may be generated before, simultaneously with, and/or after an inspection process has been performed on the sample 106.

The metrology sites may be defined in a sampling plan. The sampling plan may include wafer identification information for identifying the sample 106 and further includes position information identifying the metrology sites selected for measurement. A number and position of the sampling points may be defined in the sampling plan. The sampling plan may be initialized according to previously obtained knowledge. The metrology sites may be within exposure fields, may be outside the exposure fields, e.g., in a wafer edge area, within chip areas and/or outside the chip areas, e.g., in the kerf area of the sample 106. The sampling plan may be static or may be dynamic. In a static sampling plan, the position of one or more sampling points and/or the number of sampling points may fixed. In a dynamic sampling plan, the position of one or more sampling points may change and/or the number of sampling points may change with time.

The metrology measurements 104 may include any suitable metrology measurement of the sample 106. For example, the metrology measurements 104 may include overlay, critical dimensions (CDs), wafer shape, and the like.

The overlay may also be referred to as an overlay measurement. The overlay may be generated between two or more of the structures of the sample 106. The overlay may include the position of the overlay marks, the measurement orientation of the overlay marks, dispositioning values between two layers, quality parameters, and the like. The overlay may be a measurable error in alignment of a center of symmetry of structures. The overlay may be error between an intended pattern or structure placement and the actual pattern or structure placement. For example, the overlay may mean errors such as a lateral shift, rotation, magnification, and/or combination of such errors of a placement of an overlay target or a pattern of devices. The overlay may be position-dependent and may include at least one of a linear offset between the structures, a magnification or size reduction of the structures, and a rotation of the structures. The overlay may include direct overlay and/or registration overlay. Direct overlay may be an overlay between a structure in a layer immediately above, and adjacent or overlapping to a structure in a lower layer. Registration overlay may be an overlay of structures in different layers that are not overlapping and are spaced apart a distance. For example, an overlay target spaced apart from a functional structure may be used to acquire a registration overlay measurement.

The critical dimensions may also be referred to as critical dimension measurements. The critical dimensions may concern any feature characteristic of a critical resist feature. The critical dimensions may quantitatively describe a physical property of one of the structures and/or a positional relationship between multiple of the structures. The critical dimensions may include the position, geometric dimensions, and/or derived data of the structures of the sample 106. The geometric dimensions may include height, width, and/or length of the structures on a surface of the sample 106 within the measurement area. The critical dimensions may include spaces of critical resist features, areas of critical resist features, and the like. The critical dimensions may include a diameter of a circular resist feature, lengths of short axes and long axes of non-circular resist features, a line width of a stripe-shaped resist feature, a width of spaces between resist features, sidewall angles of resist features, areas of resist features and other properties such as line edge roughness of resist features, and the like. For example, the critical dimensions may include a width of a line or a vertical extension of a step or a trench, a sidewall angle of a protrusion extending from a surface of the sample 106, or a sidewall angle of a trench extending into a surface of the sample 106. By way of another example, the critical dimensions may include a thickness and/or composition of a topmost layer covering the sample 106 or about other physical properties or characteristics such as line edge roughness, line width roughness, overlay data, wafer shape, wafer deformation, defect density as well as about results of defect and electrical measurements.

The wafer shape may refer to other physical properties of the sample 106. For example, the wafer shape may refer to height maps, wafer bowing, wafer warping, and the like. The metrology measurements 104 may also characterize aspects of bare wafers and/or un-patterned films such as, but not limited to, wafer thickness, wafer flatness, film thickness, film flatness, refractive index, or stress.

The metrology system 100 may include a controller 108. The controller 108 may include processors 110 configured to execute program instructions maintained on memory 112 (e.g., a memory medium). Further, the controller 108 may be communicatively coupled with any of the components of the metrology system 100 including, but not limited to, the metrology sub-system 102 and any other sub-systems. In this regard, the processors 110 of the controller 108 may execute any of the various process steps described throughout the present disclosure. The controller 108 may receive the metrology measurements 104 from the metrology sub-system 102. The controller 108 may use the metrology measurements 104 for one or more purposes.

The controller 108 may be configured to perform automated process control (APC). The metrology measurements 104 may determine a variation by comparing the actual values of the metrology measurements 104 to target values of the metrology measurements 104. The comparison may be used in a control loop. The controller 108 may include control loops to control the variations of the metrology measurements 104 (e.g., overlay and/or critical dimensions). The metrology measurements 104 may be used in a feed forward and/or feed backward recipe. The metrology measurements 104 may be used to correct for the metrology measurements 104 of the sample 106 in a feed backward recipe or may be used to correct the metrology measurements 104 of the samples 106 in a feed forward recipe. The metrology measurements 104 may be used for material excursion control or for any other use of a fabrication process. The variation may be determined over a field within the sample 106, over the sample 106, and/or over a lot including multiple of the samples 106.

The controller 108 may generate a weighting map 114. The weighting map 114 may be associated with the sample 106.

The controller 108 may generate the weighting map 114 based on spatial process key process indicators (spatial process KPIs). The spatial process key process indicators may be from an aggregated historical data analysis of the sample 106 or other samples. For example, the controller 108 may generate the weighting map 114 based on process variability data, measurement tolerances, process criticality associated with a likelihood of failure, process window limits, variation of the metrology measurements 104 over time, roughness estimates, edge placement error (EPE), electrical tests, defect inspection data, metrology measurements 104 of additional samples, metrology measurements 104 of the sample 106 for previous process steps, and the like. The key process indicators may be received from the metrology sub-system 102 and/or another process tool within a semiconductor fabrication process. For example, the key process indicators may be received from multiple process tools and aggregated together for generating the weighting map 114.

The weighting map 114 may spatially vary across the sample 106. The weighting map 114 may include a two-dimensional weight for regions across the sample 106. The weighting map 114 may weigh certain regions of the sample 106 differently and according to the process variability and criticality. The weighting map 114 may weigh regions that are prone to failure more strongly than regions that are less prone to failure. The regions that are prone to failure may include regions where yield loss is expected. For example, the regions that are prone to failure may be around the edge of the sample 106. The weighting map 114 may weigh the metrology measurements 104 around the edge of the sample 106 more strongly than the metrology measurements 104 at the center of the sample 106.

The weighting map 114 may be non-symmetrical around a center axis of the sample 106. The weighting map 114 may include different weights in azimuth for a select radial distance from the center axis of the sample 106. For example, not all regions around the edge of the sample 106 may be weighed the same.

The controller 108 may generate a modeled correction 116. The modeled correction 116 may also be referred to as correctables. The controller 108 may generate the modeled correction 116 based on the metrology measurements 104 and the weighting map 114.

The controller 108 may generate the modeled correction 116 using a wafer exposure model that may interpolate the modeled correction 116 based on the metrology measurements 104 and/or the weighting map 114. In addition, the controller 108 may update the coefficients of the wafer exposure model based on the metrology measurements 104 and/or the weighting map 114.

The modeled correction 116 may be a systematic signature which is extracted from the metrology measurements 104. For example, the modeled correction 116 may be extracted from the metrology measurements 104 using polynomials. The modeled correction 116 may be defined by polynomial terms and/or principal components of the signature. The modeled correction 116 may include polynomial terms of a certain type up to a maximum order. For example, at least one further model may include all polynomial terms up to the maximum order. The maximum order of the polynomial terms may be between three and ten. The principal components of the signature may be influenced by the weighting map 114.

The modeled correction 116 may be defined by polynomial terms with polar coordinates and/or cartesian coordinates. The polynomial terms may include polar coordinates for inter-field correction. Inter-field correction may reduce substrate-level deviations. The substrate-level deviations may include effects based on deposition effects, wafer bowing, and others. The polynomial terms may include cartesian coordinates for intra-field correction and/or for intra-die corrections. Intra-field corrections may reduce reticle effects and/or design-specific effects. The intra-die corrections may reduce topography and/or sample density induced effects. The polynomial may include any suitable polynomial, such as, a Zernike polynomial, Legendre polynomial, or the like.

Zernike polynomials may be defined in the polar coordinate system. Due to the shape of the sample 106 and to the nature of the processes, many process deviations result in errors that can be comparatively well described with Zernike polynomials. A range of corrections may be determined for a given nonlinear function. The range of corrections may be higher order terms of a fitted model.

Legendre polynomials may be defined in the cartesian coordinate system. The Legendre polynomials may be a point symmetric approximation that approximates the distribution of the metrology measurements 104 in a closed form.

The modeled correction 116 may be selected to approximate the metrology measurements 104 while minimizing an error function. The coefficients of the modeled correction 116 may be obtained by using a fitting algorithm. The fitting algorithm searches for coefficients that minimize deviations between the modeled correction 116 and the metrology measurements 104. The fitting algorithm may include a least squares method (LSM).

A residual may be a measure for the remaining deviation between the modeled correction 116 and the metrology measurements 104. In particular, the total magnitude of the residuals may give an impression of the quality of the modeled correction 116. With increasing number of terms in a physical model, the overall residuals get lower. But with increasing number of terms, the modeled correction 116 may follow process-insignificant noise.

The modeled correction 116 may be generated using a regression that reduces the residuals between the modeled correction 116 and the metrology measurements 104. The regression may include a standard linear regression or the like. For example, the modeled correction 116 may reduce a root mean squared error (RMSE) between the metrology measurements 104 and the modeled correction 116. Therefore, the residuals after modeling are, on average, spread uniformly over the sample 106. By way of another example, the modeled correction 116 may reduce a weighted root mean squared error (weighted RMSE) between metrology measurements 104 and the modeled correction 116, where the weighted RMSE is weighted according to the weighting map 114. Therefore, the residuals after modeling may be reduced in areas of high weights and/or increased in areas of low weights, where the high weights and low weights are from the weighting map 114.

Different regions over the sample 106 may have different variations and errors coming from different process step. Furthermore, different regions over the sample 106 may have different specifications for the structures.

The controller 108 may use the weighting map 114 when generating the modeled correction 116. For example, the controller 108 may weigh the metrology measurements 104 with the weighting map 114 by multiplying together the metrology measurements 104 and the weighting map 114 before generating the modeled correction 116 from the metrology measurements 104 after being weighed. By way of another example, the controller 108 may weigh the residuals used to determine the modeled correction 116. For instance, a model routine (e.g., a weighted least squares regression) may multiply the residuals between the metrology measurements 104 and the modeled correction 116 with weights to the according to the weighting map 114.

The modeled correction 116 may be weighed via the weighting map 114 according to the position at which the metrology measurements 104 were generated on the sample 106. For example, the weighting map 114 and the metrology measurements 104 may include corresponding positions. The weights at the weighting map 114 from the corresponding positions may be used when generating the weighting map 114 from the metrology measurements 104.

The controller 108 may control the modeled correction 116 using the weighting map 114. The modeled correction 116 may be controlled such that the modeled correction 116 for all structures of the sample 106 are within a specified design limit. Weighing the modeled correction 116 with the weighting map 114 when generating the modeled correction 116 may adjust the spatial distribution of the residuals across the sample 106 and similarly adjust the modeled correction 116. For example, weighing the regions of the sample 106 which are prone to failure stronger in the weighting map 114 may cause lower residuals in these areas. The regions which are prone to failure may then remain within specification even with bigger variations in these regions. Thus, the weighting map 114 may be beneficial to reduce residuals in areas that are prone to failure (e.g., at the edge of the sample 106) while introducing residuals in regions where there is a big margin (e.g., at the center of the sample 106). For example, the weighting map 114 may introduce residuals in the center of the sample 106 while reducing residuals at the edge of the sample 106 to keep all dies of the sample 106 within specification with as much margin as possible.

The modeled correction 116 may include one or more process correction parameters. The process correction parameters may be defined as a function of the position coordinates. The process correction parameters may be used to compensate for process errors in the sample 106. The modeled correction 116 may include dose corrections, focus corrections, overlay corrections, and the like. The dose corrections and/or the focus corrections may be selected to compensate for intra-field deviations. For example, uncorrected illumination non-uniformities, mask aberrations, and/or projection lens aberrations may result in different imaging properties within the exposure field that may be compensated by changing the predetermined focus and/or dose values as a function of the x coordinates and the y coordinates within the exposure field.

The modeled correction 116 may be used to monitor or adjust a process tool 118. For example, the process tool 118 may be a lithography tool, a deposition tool, an etching tool, scanner tool, or the like. The modeled correction 116 may be a correction which the process tool 118 may use to perform a given process on the sample 106. The controller 108 may control the process tool 118 based on the modeled correction 116 with at least one of a feedback control or a feedforward control. For example, the modeled correction 116 may correct the process used to form the structures on the sample 106. The modeled correction 116 may include data used to correct the alignment of the process tool 118 to improve the control of subsequent lithographic patterning with respect to overlay performance. The modeled correction 116 may allow the process to proceed within predefined limits by providing feedback control and/or feedforward control to improve the alignment of the process tool 118. The modeled correction 116 may be displayed, transmitted to a higher-order process monitoring and/or administration system and/or may be used for controlling the exposure process across the complete main surface of a next sample or for a rework of the current sample.

The modeled correction 116 may include intra-die corrections and/or inter-die corrections. The intra-die corrections may include corrections within the die structures of the sample 106. The inter-die corrections may include corrections between multiple of the die structures of the sample 106.

Multiple of the samples 106 of a batch (e.g., a wafer lot) may be subjected to the same processes for forming the same structures. The modeled correction 116 may adjust the process used to form the structures on the samples 106 of the batch via the feedback control. Metrology processes may be used at various steps during a semiconductor manufacturing process to monitor and control the process.

FIG. 1B depicts an example of the metrology sub-system 102, in accordance with one or more embodiments of the present disclosure. The metrology sub-system 102 may include an illumination source 120 configured to generate an illumination beam 122. The illumination beam 122 may include one or more selected wavelengths of light including, but not limited to, ultraviolet (UV) radiation, visible radiation, or infrared (IR) radiation.

The illumination source 120 may include any type of illumination source suitable for providing an illumination beam 122. The illumination source 120 may be a laser source. For example, the illumination source 120 may include, but is not limited to, one or more narrowband laser sources, a broadband laser source, a supercontinuum laser source, a white light laser source, or the like. In this regard, the illumination source 120 may provide an illumination beam 122 having high coherence (e.g., high spatial coherence and/or temporal coherence). The illumination source 120 may be a laser-sustained plasma (LSP) source. For example, the illumination source 120 may include, but is not limited to, a LSP lamp, a LSP bulb, or a LSP chamber suitable for containing one or more elements that, when excited by a laser source into a plasma state, may emit broadband illumination. The illumination source 120 may include a lamp source. For example, the illumination source 120 may include, but is not limited to, an arc lamp, a discharge lamp, an electrode-less lamp, or the like. In this regard, the illumination source 120 may provide an illumination beam 122 having low coherence (e.g., low spatial coherence and/or temporal coherence). The illumination source 120 may include a synchrotron source.

The metrology system 100 may include a wavelength selection device 124 to control the spectrum of the illumination beam 122 for illumination of the sample 106. For example, the wavelength selection device 124 may include a tunable filter suitable for providing an illumination beam 122 with a selected spectrum (e.g., center wavelength, bandwidth, spectral profile, or the like). By way of another example, the wavelength selection device 124 may adjust one or more control settings of the illumination source 120 to directly control the spectrum of the illumination beam 122. Further, the controller 108 may be communicatively coupled to the illumination source 120 and/or the wavelength selection device 124 to adjust one or more aspects of the spectrum of the illumination beam 122.

The metrology sub-system 102 may direct the illumination beam 122 to the sample 106 via an illumination pathway 126. The illumination pathway 126 may include one or more optical components suitable for modifying and/or conditioning the illumination beam 122 as well as directing the illumination beam 122 to the sample 106. For example, the illumination pathway 126 may include, but is not required to include, one or more lenses 128 (e.g., to collimate the illumination beam 122, to relay pupil and/or field planes, or the like), one or more polarizers 130 to adjust the polarization of the illumination beam 122, one or more filters, one or more beam splitters, one or more diffusers, one or more homogenizers, one or more apodizers, one or more beam shapers, or one or more mirrors (e.g., static mirrors, translatable mirrors, scanning mirrors, or the like). The metrology sub-system 102 may include an objective lens 132 to focus the illumination beam 122 onto the sample 106 (e.g., an overlay target with overlay target elements located on two or more layers of the sample 106). In another embodiment, the sample 106 is disposed on a sample stage 134 suitable for securing the sample 106 and further configured to position the sample 106 with respect to the illumination beam 122.

The metrology sub-system 102 may include a detector 136 configured to capture radiation (e.g., sample radiation 138) emanating from the sample 106 (e.g., an overlay target on the sample 106) through a collection pathway 140 and generate one or more overlay signals indicative of overlay of two or more layers of the sample 106. The collection pathway 140 may include multiple optical elements to direct and/or modify illumination collected by the objective lens 132 including, but not limited to one or more lenses 142, one or more filters, one or more polarizers, one or more beam blocks, or one or more beamsplitters. For example, the detector 136 may receive an image of the sample 106 provided by elements in the collection pathway 140 (e.g., the objective lens 132, the one or more lenses 142, or the like). By way of another example, the detector 136 may receive radiation reflected or scattered (e.g., via specular reflection, diffuse reflection, and the like) from the sample 106. By way of another example, the detector 136 may receive radiation generated by the sample (e.g., luminescence associated with absorption of the illumination beam 122, and the like). By way of another example, the detector 136 may receive one or more diffracted orders of radiation from the sample 106 (e.g., 0-order diffraction, ±1 order diffraction, ±2 order diffraction, and the like).

The illumination pathway 126 and the collection pathway 140 of the metrology sub-system 102 may be oriented in a wide range of configurations suitable for illuminating the sample 106 with the illumination beam 122 and collecting radiation emanating from the sample 106 in response to the illumination beam 122. For example, the metrology sub-system 102 may include a beamsplitter 144 oriented such that the objective lens 132 may simultaneously direct the illumination beam 122 to the sample 106 and collect radiation emanating from the sample 106. By way of another example, the illumination pathway 126 and the collection pathway 140 may contain non-overlapping optical paths.

The detector 136 may generate the metrology measurements 104. For example, the detector 136 may generate the metrology measurements 104 based on the sample radiation 138 captured by the detector 136. The detector 136 may provide the metrology measurements 104 to the controller 108.

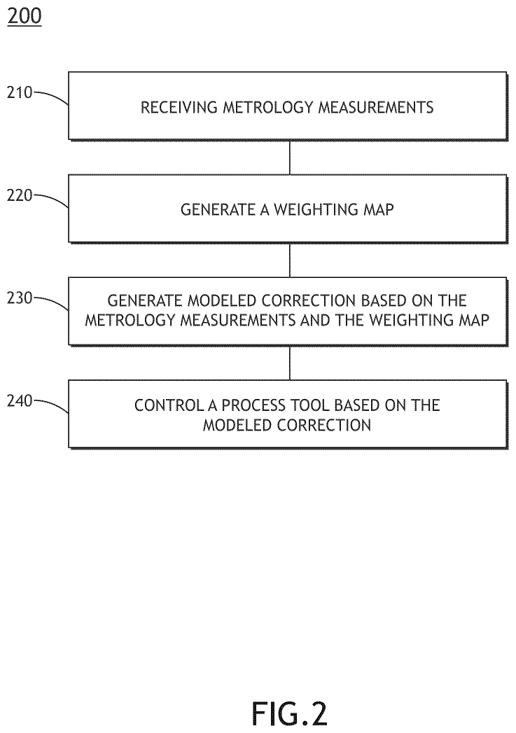

FIG. 2 depicts a flow diagram of a method 200, in accordance with one or more embodiments of the present disclosure. The embodiments and the enabling technologies described previously herein in the context of the metrology system 100 should be interpreted to extend to the method 200. It is further noted, however, that the method 200 is not limited to the architecture of the metrology system 100.

In a step 210, metrology measurements may be received. The controller 108 may receive the metrology measurements 104. The controller 108 may receive the metrology measurements 104 from the metrology sub-system 102. For example, the metrology measurements 104 may be generated by the metrology sub-system 102 and provided to the controller 108. The metrology measurements 104 may be generated at one or more positions on the sample 106.

In a step 220, a weighting map may be generated. For example, the controller 108 may generate the weighting map 114. The weighting map 114 may spatially vary across the sample 106.

In a step 230, a modeled correction may be generated based on the metrology measurements and the weighting map. For example, the controller 108 may generate the modeled correction 116 based on the metrology measurements 104 and the weighting map 114.

In a step 240, a process tool may be controlled based on the modeled correction with at least one of a feedback control or a feedforward control. For example, the controller 108 may control the process tool 118 based on the modeled correction 116 with at least one of a feedback control or a feedforward control. The structures of the sample 106 may be corrected using the modeled correction 116. For example, the controller 108 may cause the structures of the sample 106 to be corrected using the modeled correction 116 via feedforward control. The structures of subsequent of the samples in a lot may be corrected using the modeled correction 116. For example, the controller 108 may cause the structures of subsequent of the samples in a lot to be corrected using the modeled correction 116 via feedback control.

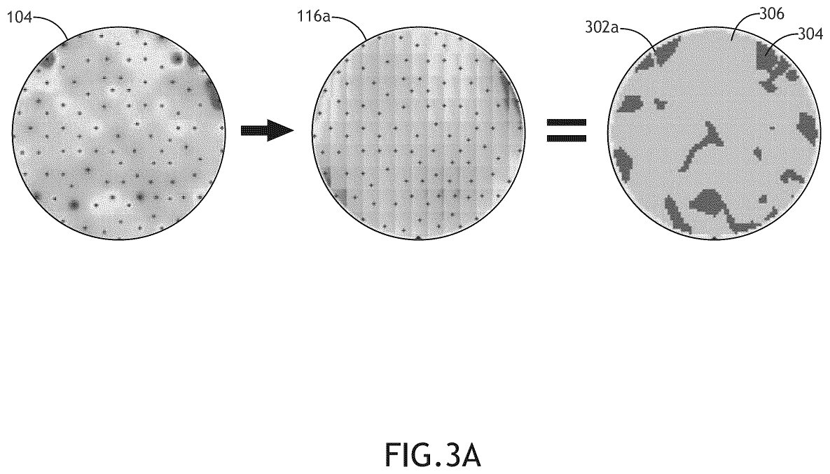

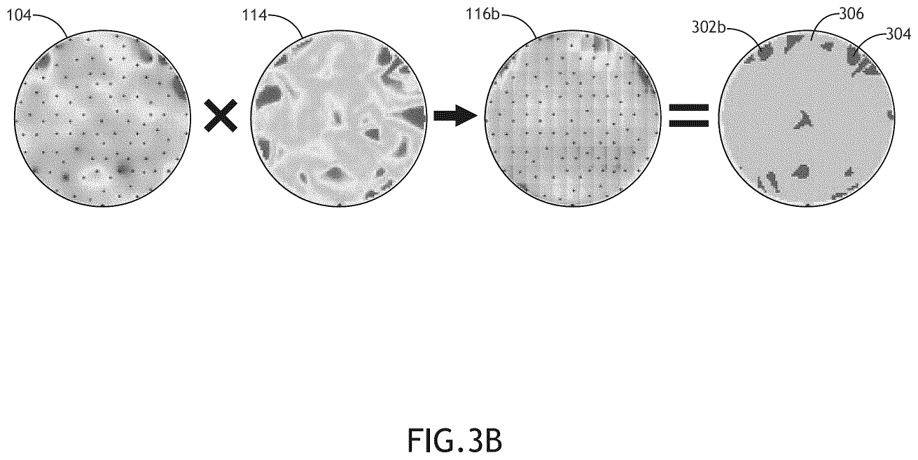

FIGS. 3A-3B depict an example of the metrology measurements 104, the weighting map 114, the modeled correction 116, and an out-of-specification map 302, in accordance with one or more embodiments of the present disclosure. In this example, the metrology measurements 104 may be measured critical dimensions and the modeled correction 116 may be modeled critical dimension corrections. The sample 106 may be corrected using the modeled correction 116 resulting in the out-of-specification map 302. The out-of-specification map 302 may be generated at an end-of-line after processing the sample 106.

In FIG. 3A, an unweighted modeled correction 116a may be generated based on the metrology measurements 104 without weighing the metrology measurements 104 according to the weighting map 114. An unweighted out-of-specification map 302a may be generated after correcting the sample 106 according to the unweighted modeled correction 116a.

In FIG. 3B, the weighting map 114 may be applied to the metrology measurements 104 to weigh the metrology measurements 104. The weighting map 114 may weigh the metrology measurements 104 by weighing regions close to the edge of the sample 106 more heavily than regions close to a center of the sample 106. In this example, the weighting map 114 may be non-symmetrical around the center axis. A weighted modeled correction 116b may be generated based on the metrology measurements 104 which are weighed with the weighting map 114. The weighted modeled correction 116b may indicate the residuals of the critical dimension are higher around the perimeter. A weighted out-of-specification map 302b may be generated after correcting the sample 106 according to the weighted modeled correction 116b.

The unweighted out-of-specification map 302a and the weighted out-of-specification map 302b may each include out-of-specification regions 304 and within-specification regions 306. The weighted out-of-specification map 302b may result in relatively less of the out-of-specification regions 304 and relatively more of the within-specification regions 306 than the unweighted out-of-specification map 302a due to weighing the metrology measurements 104 with the weighting map 114 before generating the modeled correction 116. Thus, the weighting map 114 may be beneficial to reduce the out-of-specification regions 304 and increase the within-specification regions 306.

As used throughout the present disclosure, the term “wafer” generally refers to a substrate formed of a semiconductor or non-semiconductor material. For example, a semiconductor or non-semiconductor material include, but are not limited to, monocrystalline silicon, gallium arsenide, and indium phosphide. A wafer may include one or more layers. For example, such layers may include, but are not limited to, a resist, a dielectric material, a conductive material, and a semiconductive material. Many different types of such layers are known in the art, and the term wafer as used herein is intended to encompass a wafer on which all types of such layers may be formed.

As used throughout the present disclosure, the term “substrate” generally refers to a substrate formed of a semiconductor or non-semiconductor material (e.g., thin filmed glass, or the like). For example, a semiconductor or non-semiconductor material may include, but is not limited to, monocrystalline silicon, gallium arsenide, indium phosphide, or a glass material. A substrate may include one or more layers. For example, such layers may include, but are not limited to, a resist (including a photoresist), a dielectric material, a conductive material, and a semiconductive material. Many different types of such layers are known in the art, and the term sample as used herein is intended to encompass a substrate on which all types of such layers may be formed. One or more layers formed on a substrate may be patterned or un-patterned. For example, a substrate may include a plurality of dies, each having repeatable patterned features. Formation and processing of such layers of material may ultimately result in completed devices. Many different types of devices may be formed on a substrate, and the term substrate as used herein is intended to encompass a substrate on which any type of device known in the art is being fabricated. Further, for the purposes of the present disclosure, the term substrate and wafer should be interpreted as interchangeable. In addition, for the purposes of the present disclosure, the terms patterning device, mask, and reticle should be interpreted as interchangeable.

For the purposes of the present disclosure, the term “registration measurement,” and the like may mean a measurement between two structures. For example, a registration measurement may mean a distance between two structures as projected onto two planes along a direction (e.g., X-direction, Y-direction). For example, such a direction may be orthogonal to a depth direction through layers of a sample. In this regard, a registration measurement may be the projected “X component” of a vector between two structures. For example, a registration measurement may be based on a single image where both structures are within the field of view of the image and a distance between structures in the image may be used to derive the registration measurement between the structures. In another example, a registration measurement is acquired as follows: first, imaging a position of a respective structure; then, moving the sample relative to the metrology sub-system by a precisely known distance; and finally, imaging a different structure. The positions (e.g., center positions) of the structures in the images and the known distance the sample was moved may be used to acquire the registration measurement between the structures. In another example, registration measurements may be mathematically determined between three or more structures using two or more registration measurements. For instance, the X components of a registration measurement between a first and second structure, and a registration measurement between the second structure and a third structure may be combined to determine the X component registration measurement between the first and third structure. It should be noted that examples of registration measurements in the present disclosure are provided for illustrative purposes and should not be interpreted as limiting, and any number of registration measurements (whether based on other registration measurements or not) to any number and type of structures may be combined to determine registration measurements between various structures.

The controller 108 may include one or more controllers housed in a common housing or within multiple housings. In this way, any controller or combination of controllers may be separately packaged as a module suitable for integration into a system. Further, the controllers may analyze data and feed the data to additional components within the system or external to the system.

The processors 110 of the controller 108 may be communicatively coupled to memory 112, where the processors 110 may be configured to execute a set of program instructions maintained in memory 112, and the set of program instructions may be configured to cause the processors 110 to carry out various functions and steps of the present disclosure.

It is noted herein that the one or more components of metrology system 100 may be communicatively coupled to the various other components of metrology system 100 in any manner known in the art. For example, the processors 110 may be communicatively coupled to each other and other components via a wireline (e.g., copper wire, fiber optic cable, and the like) or wireless connection (e.g., RF coupling, IR coupling, WiMax, Bluetooth, 3G, 4G, 4G LTE, 5G, and the like). By way of another example, the controller 108 may be communicatively coupled to one or more components of metrology system 100 via any wireline or wireless connection known in the art.

The processors 110 may include any one or more processing elements known in the art. In this sense, the processors 110 may include any microprocessor-type device configured to execute software algorithms and/or instructions. In embodiments, the processors 110 may consist of a desktop computer, mainframe computer system, workstation, image computer, parallel processor, or other computer system (e.g., networked computer) configured to execute a program configured to operate the metrology system 100, as described throughout the present disclosure. It should be recognized that the steps described throughout the present disclosure may be carried out by a single computer system or, alternatively, multiple computer systems. Furthermore, it should be recognized that the steps described throughout the present disclosure may be carried out on any one or more of the processors 110. In general, the term “processor” may be broadly defined to encompass any device having one or more processing elements, which execute program instructions from memory 112. Moreover, different subsystems of the metrology system 100 (e.g., metrology sub-system 102, controller 108, user interface, and the like) may include processor or logic elements suitable for carrying out at least a portion of the steps described throughout the present disclosure. Therefore, the above description should not be interpreted as a limitation on the present disclosure but merely an illustration.

The memory 112 may include any storage medium known in the art suitable for storing program instructions executable by the processors 110 and the data received from the metrology system 100. For example, the memory 112 may include a non-transitory memory medium. For instance, the memory 112 may include, but is not limited to, a read-only memory (ROM), a random-access memory (RAM), a magnetic or optical memory (e.g., disk), a magnetic tape, a solid-state drive, and the like. It is further noted that the memory 112 may be housed in a common controller housing with the processors 110. In an alternative embodiment, the memory 112 may be located remotely with respect to the physical location of the processors 110, controller 108, and the like. In another embodiment, the memory 112 may maintain program instructions for causing the processors 110 to carry out the various steps described through the present disclosure.

A user interface may be communicatively coupled to the controller 108. The user interface may include, but is not limited to, one or more desktops, tablets, smartphones, smart watches, or the like. The user interface may include a display used to display data of the metrology system 100 to a user. The display of the user interface may include any display known in the art. For example, the display may include, but is not limited to, a liquid crystal display (LCD), an organic light-emitting diode (OLED) based display, or a CRT display. Any display device capable of integration with a user interface is suitable for implementation in the present disclosure. A user may input selections and/or instructions responsive to data displayed to the user via a user input device of the user interface.

In the case of a control algorithm, one or more program instructions or methods may be configured to operate via proportional control, feedback control, feedforward control, integral control, proportional-derivative (PD) control, proportional-integral (PI) control, proportional-integral-derivative (PID) control, or the like.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period. For example, the memory may be random access memory (RAM), and the results may not necessarily persist indefinitely in the memory.

The results may be stored on a system (e.g., external controller and memory such as external server) that is external to the metrology sub-system 102. Examples of such systems include systems configured to compile and reduce data (e.g., results) to generate relevant root cause and yield analysis information. For instance, software (e.g., OVALiS software) on external systems may support on-product process optimization, diagnostics, monitoring and control for lithography and other patterning steps that are critical to IC manufacturing. Further, 5D Analyzer advanced data analysis and patterning control software may be used to provide for an extendible, open architecture that accepts data from a wide range of metrology and process tools to enable advanced analysis, characterization, and real-time control of fab-wide process variations.

It is further contemplated that each of the embodiments of the methods described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mixable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A controller of a metrology system, the controller comprising:
one or more processors configured to execute program instructions causing the one or more processors to:
receive one or more metrology measurements of a sample;
generate a weighting map associated with the sample, wherein the weighting map spatially varies across the sample; and
generate a modeled correction based on the one or more metrology measurements and the weighting map, wherein the modeled correction is weighed via the weighting map according to a position at which the one or more metrology measurements were generated on the sample.

2. The controller of claim 1, wherein the one or more metrology measurements comprise at least one of an overlay or one or more critical dimensions.

3. The controller of claim 1, wherein the weighting map is generated based on process variability data.

4. The controller of claim 1, wherein the weighting map is generated based on process critical data associated with a likelihood of failure, wherein the weighting map is configured to weigh regions on the sample that are prone to failure more strongly than regions that are less prone to failure.

5. The controller of claim 1, wherein the weighting map is generated based on at least one of a process window limit, a variation of the one or more metrology measurements over time, an edge placement error, an electrical test, or defect inspection data.

6. The controller of claim 1, wherein the weighting map is generated based on one or more additional metrology measurements of one or more additional samples.

7. The controller of claim 1, wherein the weighting map is generated based on one or more additional metrology measurements of the sample for a previous process step.

8. The controller of claim 1, wherein the weighting map is non-symmetrical around a center axis of the sample.

9. The controller of claim 1, wherein the modeled correction is defined by polynomial terms.

10. The controller of claim 9, wherein the polynomial terms are one of a Zernike polynomial or a Legendre polynomial.

11. The controller of claim 9, wherein a maximum order of the polynomial terms is between three and ten.

12. The controller of claim 1, wherein the modeled correction comprises at least one of a dose correction, a focus correction, or an overlay correction.

13. The controller of claim 1, wherein the controller is configured to generate the modeled correction by a regression that reduces a residual between the modeled correction and the one or more metrology measurements.

14. The controller of claim 13, wherein weighing the modeled correction with the weighting map when generating the modeled correction adjusts a spatial distribution of the residual across the sample.

15. The controller of claim 1, wherein the controller is configured to control a process tool based on the modeled correction with at least one of a feedback control or a feedforward control.

16. A metrology system comprising:
a controller comprising:
one or more processors configured to execute program instructions causing the one or more processors to:
receive one or more metrology measurements of a sample;
generate a weighting map associated with the sample, wherein the weighting map spatially varies across the sample; and
generate a modeled correction based on the one or more metrology measurements and the weighting map, wherein the modeled correction is weighed via the weighting map according to a position at which the one or more metrology measurements were generated on the sample.

17. The metrology system of claim 16, comprising a metrology sub-system, wherein the metrology sub-system is configured to generate the one or more metrology measurements of the sample, wherein the controller is configured to receive the one or more metrology measurements from the metrology sub-system.

18. The metrology system of claim 16, comprising a process tool, wherein the controller is configured to control the process tool based on the modeled correction with at least one of a feedback control or a feedforward control.

19. A method comprising:
receiving one or more metrology measurements of a sample;
generating a weighting map associated with the sample, wherein the weighting map spatially varies across the sample; and
generating a modeled correction based on the one or more metrology measurements and the weighting map, wherein the modeled correction is weighed via the weighting map according to a position at which the one or more metrology measurements were generated on the sample.

20. The method of claim 19, comprising controlling a process tool based on the modeled correction with at least one of a feedback control or a feedforward control.
